(19) United States
(12) Patent Application Publication
(10) Pub. No.: US 2026/0206643 A1
(43) Pub. Date: Jul. 16, 2026

(54) ELECTRONIC DEVICE

(71) Applicant: Advanced Semiconductor Engineering, Inc., Kaohsiung (TW)

(72) Inventors: Kuofeng HUANG, Kaohsiung (TW); Hsin-Chin CHANG, Kaohsiung (TW); Chih Lung Hung, Kaohsiung (TW); Hsin-Hua HUANG, Kaohsiung (TW); Chi Hao CHIANG, Kaohsiung (TW)

(73) Assignee: Advanced Semiconductor Engineering, Inc., Kaohsiung (TW)

(21) Appl. No.: 19/019,399

(22) Filed: Jan. 13, 2025

(51) Int. Cl. H01L 25/18; H01L 23/31; H01L 23/367; H01L 23/538; H02M 3/00

(52) U.S. Cl. CPC H10W 90/00; H02M 3/003; H10W 70/611; H10W 90/401; H10W 40/22; H10W 74/141

(57) ABSTRACT

The present disclosure provides an electronic device. The electronic device includes an operating module, a first converter, and a second converter. The first converter abuts the operating module. The second converter is opposite to the first converter. The second converter is configured to convert a first voltage from the first converter to a second voltage received by the operating module.

### BACKGROUND

### 1. Technical Field

The present disclosure relates to an electronic device.

### 2. Description of the Related Art

Power management integrated circuits (PMICs) leverage System-in-Package (SiP) technology, including double side molding, 2.5D/3D IC, etc., to integrate multiple chips or components into a package. However, to provide different types of power control and to adapt to demands of high-speed data communication, bulky passive components may be needed. As a result, the package size may be increased, and thus the layout design flexibility may be diminished.

### SUMMARY

In some arrangements, an electronic device includes an operating module, a first converter and a second converter. The first converter abuts the operating module. The second converter is opposite to the first converter. The second converter is configured to convert a first voltage from the first converter to a second voltage received by the operating module.

In some arrangements, an electronic device includes a first carrier, an operating module. a plurality of first converters, and a plurality of second converters. The first carrier has a first surface and a second surface. The operating module is disposed under the first surface. The plurality of first converters laterally overlaps the operating module. The plurality of second converters are disposed over the second surface of the first carrier and vertically overlaps the plurality of first converters.

In some arrangements, an electronic device includes a first direct current to direct current (DC/DC) converter, a second DC/DC converter, and an operating unit. The second DC/DC converter is configured to receive a first voltage from the first DC/DC converter transmitted along a first direction. The operating unit is configured to receive a second voltage from the second DC/DC converter transmitted along a second direction opposite to the first direction.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a cross-sectional view of an electronic device, in accordance with some arrangements of the present disclosure.

FIG. 1B illustrates a layout of an operating module, in accordance with some arrangements of the present disclosure.

FIG. 2 illustrates a cross-sectional view of a DC/DC converter, in accordance with some arrangements of the present disclosure.

FIG. 3 illustrates a top of an electronic device, in accordance with some arrangements of the present disclosure.

FIG. 4 illustrates a cross-sectional view along line A-A′ of the electronic device as shown in FIG. 3, in accordance with some arrangements of the present disclosure.

FIG. 5 illustrates a top of an electronic device, in accordance with some arrangements of the present disclosure.

FIG. 6 illustrates a cross-sectional view along line B-B′ of the electronic device as shown in FIG. 5, in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

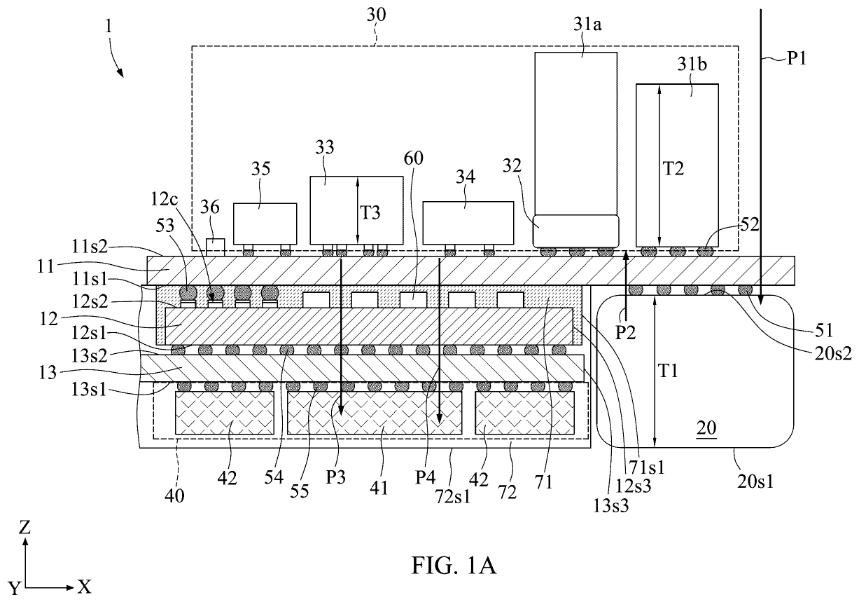

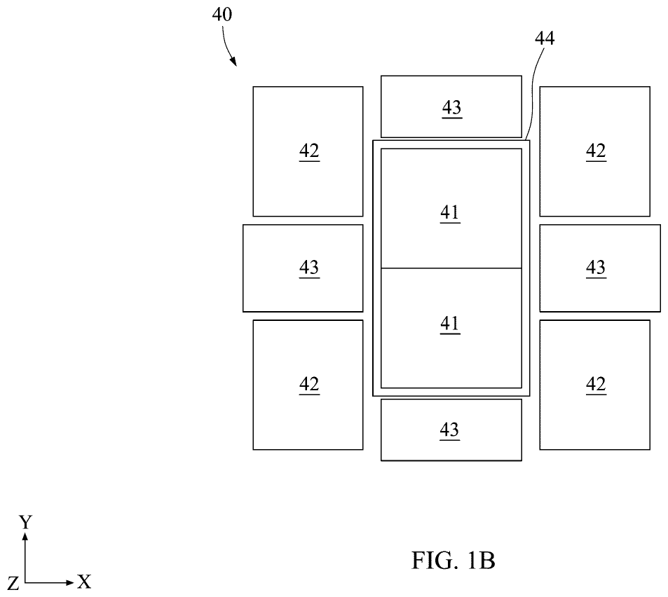

FIG. 1A illustrates a cross-sectional view of an electronic device 1, in accordance with some arrangements of the present disclosure. In some arrangements, the electronic device 1 includes a carrier 11, a DC/DC converter 20, a DC/DC converter 30, and an operating module 40.

The carrier 11 may be formed as a printed circuit board (PCB), flexible printed circuit board (FPCB), or other suitable circuit structures. The carrier 11 may include multiple metal layers separated from one another by layers of dielectric material and interconnected by electrically conductive vias. In some embodiments, the carrier 11 may be formed of an epoxy resin, a fiberglass-reinforced epoxy resin, an epoxy resin with inorganic fillers, a ceramic material, or a polymer material such as polyimide. The carrier 11 may have a surface 11s1 (or lower surface) and a surface 11s2 (or upper surface) opposite to the surface 11s1.

In some arrangements, the DC/DC converter 20 (or first power conversion stage or converter or electrical converter) may be disposed on or under the surface 11s1 of the carrier 11. In some arrangements, the DC/DC converter 20 may be configured to convert a high voltage (e.g., 48 V) to a lower voltage (e.g., 12 V). In some arrangements, the DC/DC converter 20 may include at least one power module, which includes a transistor(s), a diode(s), a capacitor(s), an inductor(s), and/or other suitable elements.

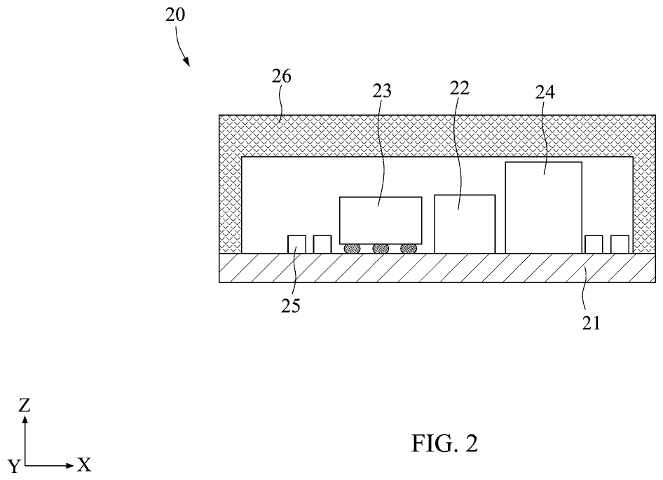

FIG. 2 illustrates a cross-sectional view of the DC/DC converter 20 as shown in FIG. 1A, in accordance with some arrangements of the present disclosure. In some arrangements, the DC/DC converter 20 may include a circuit structure 21, an active component 22, a controller 23, passive component 24, passive component 25, and housing 26. It should be noted that the DC/DC converter 20 can include more elements and/or components based on the requirements.

The circuit structure 21 may be formed as a PCB, FPCB, or other suitable circuit structures. The circuit structure 21 may include multiple metal layers separated from one another by layers of dielectric material and interconnected by electrically conductive vias. In some embodiments, the circuit structure 21 may be formed of an epoxy resin, a fiberglass-reinforced epoxy resin, an epoxy resin with inorganic fillers, a ceramic material, or a polymer material such as polyimide.

The active component 22, controller 23, passive components 24 and 25 may be disposed on and electrically connected to the circuit structure 21. In some arrangements, the active component 22 may be a transistor, which includes a gate terminal, a drain terminal, and a source terminal. In some arrangements, the controller 23 may be a switch, which is configured to turn on or turn off the active component 22. In some arrangements, the passive component 24 may be configured to regulate the power of the DC/DC converter 20. The passive component 24 may include an inductor or other suitable elements. In some arrangements, the passive component 25 may be configured to regulate the power of the DC/DC converter 20. The passive component 25 may include a capacitor (e.g., a deep trench capacitor (DTC), a multi-layer ceramic capacitor (MLCC) or other capacitors), or other suitable elements.

The housing 26 may be disposed on or over the circuit structure 21. The housing 26 may cover the active component 22, controller 23, passive components 24 and 25. In some arrangements, the housing 26 may be configured to transmit the heat from the DC/DC converter 20 to the surroundings. In some arrangements, the housing 26 may include aluminum (Al), copper (Cu), chromium (Cr), tin (Sn), gold (Au), silver (Ag), nickel (Ni) or stainless steel, or a mixture, an alloy, or other combination thereof.

Please Refer back to FIG. 1A, the DC/DC converter 20 may have a surface 20s1 (or a lower surface) and a surface 20s2 (or upper surface) opposite to the surface 20s1. In some arrangements, the surface 20s2 may face the carrier 11 (or DC/DC converter 30). In some arrangements, the surface 20s2 may be an active surface. In this disclosure, the active surface may refer to a surface on which an active circuit or an active circuit region is disposed or refer to a surface through which a signal (e.g., power signal or data signal) passes. The DC/DC converter 20 may be electrically connected to the carrier 11 through electrical connectors 51. The electrical connectors 51 may include a reflowable material. The electrical connectors 51 may be or include electrical contacts, such as solder balls, conductive bumps, or the like. The electrical connectors 51 may include alloys of gold and tin solder or alloys of silver and tin solder, or other suitable materials.

The DC/DC converter 20 may be configured to receive a power P1 (or voltage) from an external device (not shown). In some arrangements, the carrier 11 is configured to transmit the electrical path (or power path) conducting the power P1. In some arrangements, the power P1 may be transmitted along the substantially negative Z-direction. The DC/DC converter 20 may be configured to provide the DC/DC converter 30 with a power P2 (or voltage). In some arrangements, the carrier 11 is configured to transmit the electrical path (or power path) conducting the power P2. In some arrangements, the power P2 may be transmitted along the substantially positive Z-direction.

The DC/DC converter 20 may have a thickness T1. In some arrangements, the thickness T1 may range between about 3 mm and 7 mm, such as 3 mm, 4 mm, 5 mm, 6 mm, or 7 mm.

In some arrangements, the DC/DC converter 30 (or second power conversion stage or converter or electrical converter) may be disposed on or over the surface 11s2 of the carrier 11. In some arrangements, the DC/DC converter 30 may be configured to convert a high voltage (e.g., 12 V) to a lower voltage (e.g., 8 V, 6 V, 4 V, 2 V, or less).

In some arrangements, the DC/DC converter 30 may vertically overlap the DC/DC converter 20 or overlap the DC/DC converter 20 along the substantial Z direction.

In some arrangements, the DC/DC converter 30 may include a voltage regulator 31a, a voltage regulator 31b, a passive component 32, a voltage regulator 33, a controller 34, a passive component 35, and a passive component 36. It should be noted that the DC/DC converter 20 can include more elements and/or components based on the requirements.

In some arrangements, the voltage regulators 31a and 31b may be configured to transmit a high voltage (e.g., 12 V) to a lower voltage (e.g., 8 V or 6 V). The voltage regulators 31a and 31b may be electrically connected to the carrier 11. The voltage regulators 31a and 31b may include multiple elements on a circuit structure (e.g., PCB). For example, the voltage regulators 31a and 31b may include a transistor(s), a controller(s), and a passive element(s). In some arrangements, the voltage regulator 31b may vertically overlap the DC/DC converter 20 or overlap the DC/DC converter 20 along the substantial Z direction.

In some arrangements, the passive component 32 may be disposed between the voltage regulator 31a and the carrier 11. The passive component 32 may be configured to regulate the power from the voltage regulator 31a. The passive component 32 may be electrically connected to the voltage regulator 31a for providing a suitable output voltage. In some arrangements, the passive component 32 may include an output capacitor (Cout) or other suitable elements. For example, the power regulated by the voltage regulator 31a may be transmitted to the carrier 11 through the passive component 32.

In some arrangements, the voltage regulator 33 may be configured to transmit a high voltage (e.g., 12 V) to a lower voltage (e.g., 4 V, 3.3 V, 2 V or less). The voltage regulator 33 may be electrically connected to the carrier 11. In some arrangements, the controller 34 may be electrically connected to the voltage regulator 33 through the carrier 11. In some arrangements, the controller 34 may be configured to turn on or turn off the voltage regulator 33.

In some arrangements, the passive components 35 and 36 may be configured to regulate the power from the voltage regulators 31a, 31b, 33, and/or other devices. The passive components 35 and 36 may be electrically connected to the carrier 11. In some arrangements, the passive components 35 and 36 may include inductors, capacitors, resistors, or other suitable passive elements.

The electronic device 1 may include electrical connectors 52. The electrical connectors 52 may be configured to connect the components (e.g., voltage regulator 31b) of the DC/DC converter 30 and the carrier 11. The electrical connectors 52 may include one or more elements. For example, the electrical connectors 52 may include a reflowable material. The electrical connectors 52 may be or include electrical contacts, such as solder balls, conductive bumps, or the like. The electrical connectors 52 may include alloys of gold and tin solder or alloys of silver and tin solder, or other suitable materials. The electrical connectors 52 may include conductive pads which include metallic and/or alloy materials.

In some arrangements, the components of the DC/DC converter 30 may have different thicknesses. For example, the voltage regulator 31b may have a thickness T2 greater than the thickness T1, and the voltage regulator 33 may have a thickness T3 less than the thickness T1. In some arrangements, the thickness T2 may be greater than 7 mm, such as 7 mm, 8 mm, 9 mm, 10 mm or more. In some arrangements, the thickness T3 may be less than 3 mm, such as 3 mm, 2 mm, 1 mm or less.

In some arrangements, the DC/DC converter 30 may occupy a surface area, which may be defined as a projection area onto the surface of the carrier 11, greater than that of the DC/DC converter 20. In some arrangements, each of the components of the DC/DC converter 30 may occupy a surface area less than that of the DC/DC converter 20. For example, the voltage regulator 31b may have a surface area less than that of the DC/DC converter 20.

In some arrangements, the DC/DC converter 30 may be configured to provide the operating module 40 with one or more powers. For example, the DC/DC converter 30 may be configured to provide the operating module 40 with a power P3 (or voltage) and a power P4 (or voltage). In some arrangements, the power P3 may be different from the power P4. In some arrangements, the carrier 11 is configured to transmit the electrical paths (or power path) conducting the power P3 and the power P4. In some arrangements, the power P3 and power P4 may be transmitted along the substantially negative Z-direction. In some arrangements, the DC/DC converters 20 and 30 may be collectively configured to function as a voltage regulated module which provides the operating module 40 with a regulated power(s).

In some arrangements, the electronic device 1 may further include a carrier 12. In some arrangements, the carrier 12 may be disposed on or under the surface 11s1 of the carrier 11. In some arrangements, the carrier 12 may partially overlap the carrier 11 along the substantial Z direction. In some arrangements, the carrier 12 may laterally overlap the DC/DC converter 20 or overlap the DC/DC converter 20 along the substantial X direction. The carrier 12 may be formed as a PCB, FPCB, or other suitable circuit structures. The carrier 12 may include multiple metal layers separated from one another by layers of dielectric material and interconnected by electrically conductive vias. In some embodiments, the carrier 12 may be formed of an epoxy resin, a fiberglass-reinforced epoxy resin, an epoxy resin with inorganic fillers, a ceramic material, or a polymer material such as polyimide. The carrier 12 may have a surface 12s1 (or lower surface), a surface 12s2 (or upper surface) opposite to the surface 12s1, and a surface 12s3 (or lateral surface) extending between the surfaces 12s1 and 12s2. In some arrangements, the dimension (e.g., surface area) of the carrier 12 may be less than that of the carrier 11. In some arrangements, the carrier 11 may overhang the carrier 12. For example, the edges (or lateral surface) of the carrier 11 may exceed the edges (or lateral surface) of the carrier 12.

In some arrangements, the carrier 12 may be electrically connected to the carrier 11 through electrical connectors 53 and conductive pads 12c over the surface 12s2 of the carrier 12. The electrical connectors 53 may include a reflowable material. The electrical connectors 53 may be or include electrical contacts, such as solder balls, conductive bumps, or the like. The electrical connectors 53 may include alloys of gold and tin solder or alloys of silver and tin solder, or other suitable materials. In some arrangements, the carrier 12 is configured to transmit the electrical path (or power path) conducting the power P3 and the power P4.

In some arrangements, the electronic device 1 may further include passive components 60. In some arrangements, the passive components 60 may be disposed on or over the surface 12s2 of the carrier 12. The passive components 60 may be electrically connected to the carrier 12. In some arrangements, the passive components 60 may be disposed between the carriers 11 and 12. The passive components 60 may be electrically connected to the carrier 12. In some arrangements, the passive components 60 may be configured to regulate the power (e.g., powers P3 and P4) from the DC/DC converter 30 toward the operating module 40. In some arrangements, the passive components 60 may include capacitors. In some arrangements, the passive component 60 may include an input capacitor (Cin) through which the power flows before being delivered to the voltage regulators 31a and 31b. In some arrangements, the passive component 60 may include an output capacitor through which the power flows after being transmitted from the voltage regulators 31a and 31b.

In some arrangements, the passive components 60 may laterally overlap the DC/DC converter 20 or overlap the DC/DC converter 20 along the substantial X direction. In some arrangements, the passive components 60 may include capacitors, inductors, or other suitable passive elements. In some arrangements, the passive components 60 may be regarded as a portion of the second power conversion stage (e.g., DC/DC converter 30).

In some arrangements, the electronic device 1 may include a carrier 13. In some arrangements, the carrier 13 may be disposed on or under the surface 12s1 of the carrier 11. In some arrangements, the carrier 13 may partially overlap the carrier 11 along the substantial Z direction. In some arrangements, the carrier 13 may overlap the carrier 12 along the substantial Z direction. In some arrangements, the carrier 13 may partially overlap the DC/DC converter 30 along the substantial Z direction. In some arrangements, the carrier 13 may laterally overlap the DC/DC converter 20 or overlap the DC/DC converter 20 along the substantial X direction. In some arrangements, the carrier 13 may include a semiconductor substrate, such as silicon, germanium, and other group III-V and group IV materials. The carrier 13 may include metal lines and vias, including but not limited to through-silicon vias (TSVs) for interconnection. In some arrangements, the carrier 13 may include a wafer, a panel form or other suitable forms. In some arrangements, the carrier 13 is configured to transmit the electrical path (or power path) conducting the power P3 and the power P4. The carrier 13 may have a surface 13s1 (or lower surface), a surface 13s2 (or upper surface) opposite to the surface 13s1, and a surface 13s3 (or lateral surface) extending between the surfaces 13s1 and 13s2.

The carrier 13 may be electrically connected to the carrier 12 through electrical connectors 54. The electrical connectors 54 may include a reflowable material. The electrical connectors 54 may be or include electrical contacts, such as solder balls, conductive bumps, or the like. The electrical connectors 54 may include alloys of gold and tin solder or alloys of silver and tin solder, or other suitable materials.

In some arrangements, the operating module 40 may be disposed on or under the surface 13s1 of the carrier 13. In some arrangements, the operating module 40 may be configured to generate non-power signals, such as analog signals, digital signals, clock signals or other electrical signals other than power signals. In some arrangements, the operating module 40 may vertically overlap the carrier 12 or overlap the carrier 12 along the substantial Z direction. In some arrangements, the operating module 40 may vertically overlap the carrier 11 or overlap the carrier 11 along the substantial Z direction. In some arrangements, the operating module 40 may vertically overlap the DC/DC converter 30 or overlap the DC/DC converter 30 along the substantial Z direction. In some arrangements, the operating module 40 may laterally overlap the DC/DC converter 20 or overlap the DC/DC converter 20 along the substantial Z direction. In some arrangements, the operating module 40 may be configured to receive the power P3 and power P4 from the DC/DC converter 30.

The operating module 40 may include electronic components 41 and 42. In some arrangements, the electronic components 41 and 42 may be disposed on or under the surface 13s1 of the carrier 13. In some arrangements, the electronic component 41 may include a processor or other suitable components. In some arrangements, the electronic component 41 may include an active device, such as a central processing unit (CPU), a microprocessor unit (MPU), a graphics processing unit (GPU), a microcontroller unit (MCU), radio frequency integrated circuit (RFIC), an application-specific IC (ASIC), a field-programmable gate array (FPGA), or another type of IC. In some arrangements, the electronic component 41 may include a data storage unit or other suitable components. The electronic component 42 may be electrically connected to the electronic component 41 through the carrier 13. The electronic component 42 may be disposed on or under the surface 13s1 of the carrier 13. In some arrangements, the electronic component 42 may be configured to storage the signals from the electronic component 41 and/or other devices. In some arrangements, the electronic component 42 may include a high band memory (HBM) die, dynamic random access memory (DRAM) die, static random access memory (SRAM) die, or other suitable memory devices.

In some arrangements, the electronic components 41 and 42 may be electrically connected to the carrier 13 through electrical connectors 55. The electrical connectors 55 may include a reflowable material. The electrical connectors 55 may be or include electrical contacts, such as solder balls, conductive bumps, or the like. The electrical connectors 55 may include alloys of gold and tin solder or alloys of silver and tin solder, or other suitable materials.

Please refer to FIG. 1B, which illustrates the layout of the operating module 40. The operating module 40 may further include electronic components 43. The electronic component 43 may be configured to receive the regulated power from the DC/DC converter 30. The electronic component 43 may be configured to output the signal(s) processed by the operating module 40. For example, the electronic components 43 may include input/output dies. In some arrangements, the operating module 40 may further include an interposer 44 configured to support the electronic components 41. In this arrangement, the interposer 44 may be disposed between the carrier 13 and the electronic component 41.

In some arrangements, the electronic device 1 may further include an encapsulant 71. In some arrangements, the encapsulant 71 may disposed on or under the surface 11s1 of the carrier 11. In some arrangements, the encapsulant 71 may disposed on or over the surface 12s2 of the carrier 12. In some arrangements, the encapsulant 71 may cover the surface 12s3 of the carrier 12. In some arrangements, the encapsulant 71 may encapsulate the passive components 60. In some arrangements, the encapsulant 71 may be in contact with the surface 11s1 of the carrier 11. In some arrangements, the encapsulant 71 may encapsulate the electrical connectors 53. The encapsulant 71 may include a molding compound. The encapsulant 71 may include a novolac-based resin, an epoxy-based resin, a silicone-based resin, or another suitable material. Suitable fillers may also be included, such as powdered SiO2. The encapsulant 71 may be applied using any of a number of molding techniques, such as compression molding, injection molding, or transfer molding.

In some arrangements, the electronic device 1 may further include an encapsulant 72. In some arrangements, the encapsulant 72 may encapsulate the surface 12s3 of the carrier 12. In some arrangements, the encapsulant 72 may encapsulate the surface 13s3 of the carrier 13. In some arrangements, the encapsulant 72 may encapsulate the encapsulant 71. In some arrangements, the encapsulant 72 may cover a surface 71s1 (or lateral surface) the encapsulant 71. In some arrangements, the encapsulant 72 may be in contact with the surface 11s1 of the carrier 11. In some arrangements, the encapsulant 72 may encapsulate the operating module 40. In some arrangements, the encapsulant 72 may encapsulate the electronic components 41 and 42. The encapsulant 72 may have a surface 72s1 (or lower surface). In some arrangements, the surface 72s1 may be at an elevation substantially the same as that of the surface 20s1 with respect to surface 11s1 of the carrier 11. The encapsulant 72 may include a molding compound. The encapsulant 72 may include a novolac-based resin, an epoxy-based resin, a silicone-based resin, or another suitable material. Suitable fillers may also be included, such as powdered SiO₂. The encapsulant 72 may be applied using any of a number of molding techniques, such as compression molding, injection molding, or transfer molding.

In some cases, the DC/DC converter 30 may occupy a larger area than the DC/DC converter 20. In this embodiment, the DC/DC converter 30 and the DC/DC converter 20 are positioned on opposite sides of the carrier 11. Additionally, the operating module 40 and the DC/DC converter 20 are located on the same side of the carrier 11, which helps to minimize the overall dimensions (e.g., surface area extending along the XY plane) of the electronic device 1. Furthermore, in this arrangement, the DC/DC converter 30 is designed to receive power from the DC/DC converter 20 via a vertical path, which is shorter than the path in a comparative example where both the first and second power conversion stages are situated on the same side.

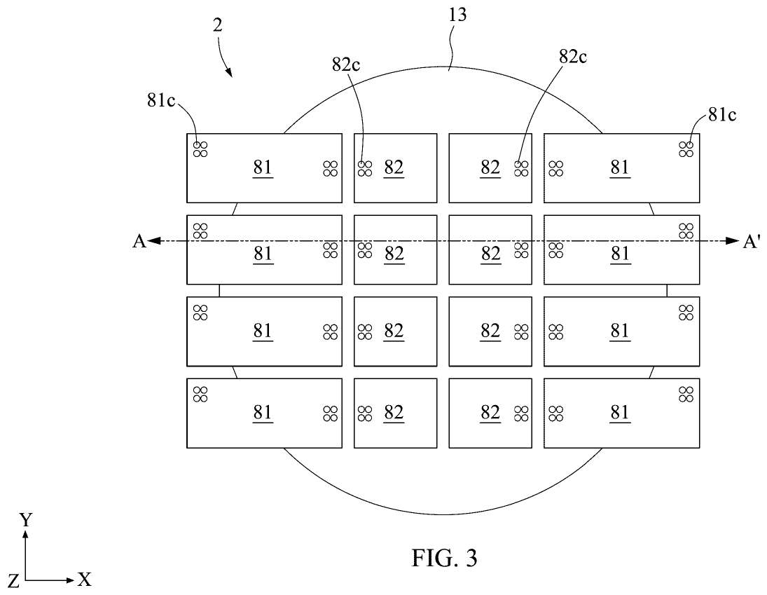

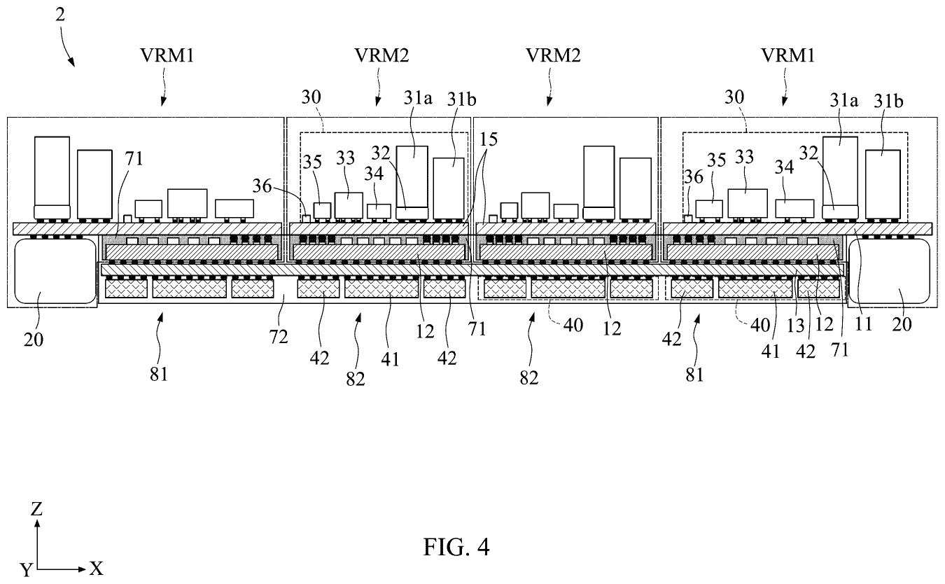

FIGS. 3 and 4 illustrate an electronic device 2, in accordance with some arrangements of the present disclosure. In some arrangements, the electronic device 2 may include packages 81 and packages 82 over the carrier 13. As shown in FIG. 3, the packages 82 may be disposed between the packages 81 along the substantial X direction. In some arrangements, each of the packages 82 may have a dimension (e.g., a surface area) less than that of the packages 81. In some arrangements, each of the packages 81 may have a profile different from that of the carrier 13. In some arrangements, each of the packages 82 may have a profile different from that of the carrier 13. In some arrangements, each of the packages 81 and 82 may have a rectangular profile or other suitable profiles. In some arrangements, the carrier 13 may have a circular profile, oval profile, or other suitable profiles. In some arrangements, each of the packages 81 may have a dimension (e.g., a surface area) less than that of the carrier 13. In some arrangements, a portion of the packages 81 may be free from overlapping the carrier 13 along the substantial Z direction. The packages 81 may include electrical connectors 81c configured to receive a power signal and/or a non-power signal. The packages 82 may include electrical connectors 82c configured to receive a power signal and/or a non-power signal. The packages 81 may be disposed on the peripheral region of the carrier 13. Each of the packages 81 may overhang the carrier 13. For example, a portion of the package 81 may be free from overlapping the carrier 13 along the substantial Z direction.

As shown in FIG. 4, the electronic device 2 may include multiple DC/DC converters 20, DC/DC converters 30, and operating modules 40 organized within the packages 81 and 82. The package 81 may include a structure the same as or similar to that of the electronic device 1 as shown in FIG. 2. In some arrangements, the package 82 may include a structure similar to that of the package 81 except that the package 82 includes a carrier 15 replacing the carrier 11.

The carrier 15 may be formed as a PCB, FPCB, or other suitable circuit structures. In some embodiments, the dimension (e.g., surface area) of the carrier 15 may be less than that of the carrier 11.

In some arrangements, the packages 82 may be configured to provide the operating module 40 with power signals. In some arrangements, the packages 82 do not include the DC/DC converter 20. That is, no DC/DC converters 20 are attached to the carrier 15. In some arrangements, the operating module 40 may be disposed between the DC/DC converters 20. The carriers 12 may be disposed between the DC/DC converters 20.

Further, as shown in FIG. 4, multiple carriers 12 may be supported by one carrier 13. In some arrangements, multiple operating modules 40 are supported by one carrier 13. The carrier 13 may be disposed between the DC/DC converters in a cross-sectional view. The encapsulant 72 may encapsulate multiple encapsulants 71. The encapsulant 72 may encapsulate multiple operating modules 40. The encapsulant 72 is disposed under the carriers 11 and 15. Further, each operating modules 40 may be communicated by the carrier 13.

In this embodiment, the DC/DC converters 30 and the DC/DC converters 20 are positioned on opposite sides of the carrier 11. Additionally, the operating modules 40 and the DC/DC converters 20 are located on the same side of the carrier 11, which helps to minimize the overall dimensions (e.g., surface area extending along the XY plane) of the electronic device 2.

In some arrangements, the electronic device 2 may include voltage regulated modules 1 (VRMs1) and voltage regulated modules 2 (VRMs2). In some arrangements, the VRMs1 may include the DC/DC converters 20 and 30, the passive components 60, and other suitable components. In some arrangements, the VRMs2 may include the DC/DC converter 30, the passive components 60, and other suitable components. In some arrangements, each of the VRMs1 and VRMs2 can be configured to supply a regulated power to the single operating module 40 independently.

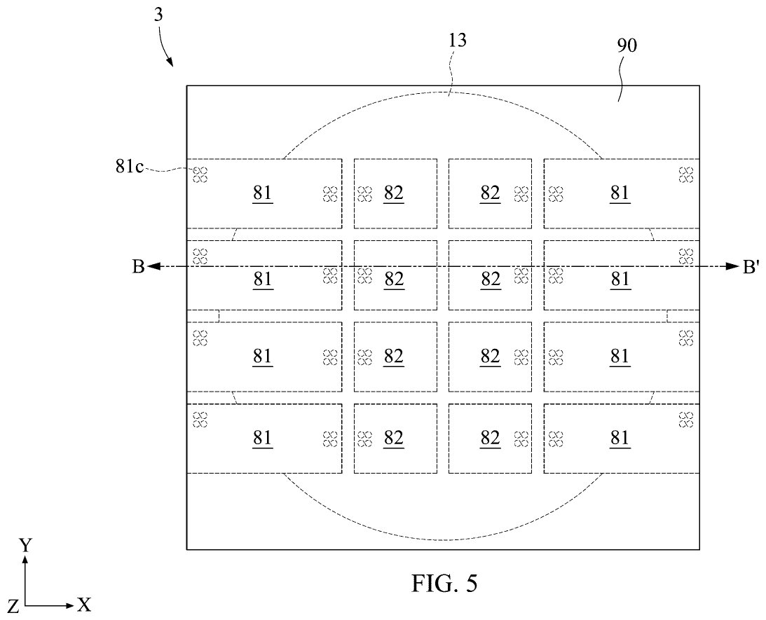

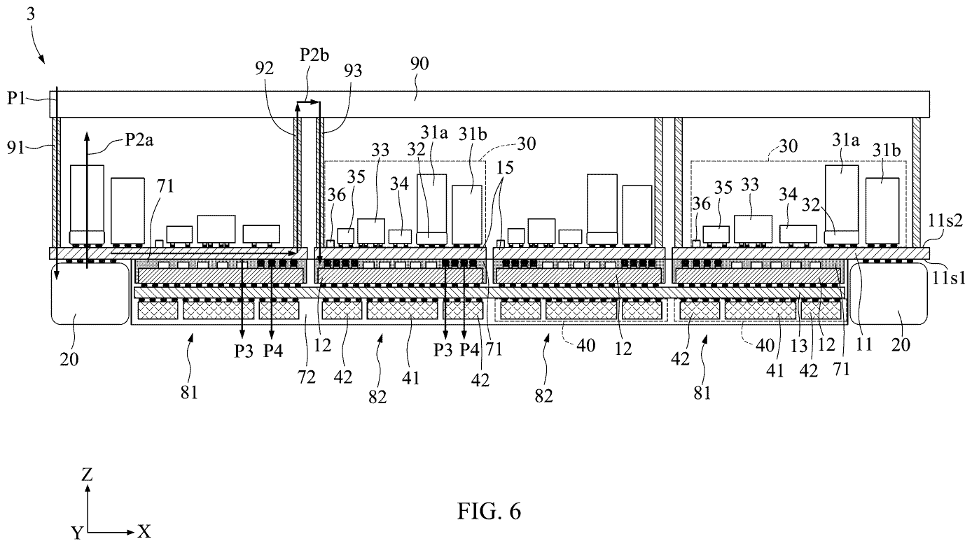

FIGS. 5 and 6 illustrate an electronic device 3, in accordance with some arrangements of the present disclosure. The electronic device 3 is similar to the electronic device 2 except for the differences described as follows.

In some arrangements, the electronic device 3 may further include a circuit structure 90 and conductive elements 91, 92, and 93. As shown in FIG. 5, the circuit structure 90 may cover the packages 81 and 82.

As shown in FIG. 6, the circuit structure 90 (or power delivery board) may be disposed on or over the surface 11s2 of the carrier 11. In some arrangements, the circuit structure 90 may be configured to provide the DC/DC converter 20 with a relatively great power (e.g., 48 V). For example, the circuit structure 90 may be configured to provide the DC/DC converter 20 with the power P1 through the conductive element 91. In some arrangements, the circuit structure 90 may include a PCB, FPCB, or other suitable circuit structures. One or more electronic components (not shown) may be disposed on or over the circuit structure 90. For example, the electronic device 3 may include a power management integrated circuit (PMIC) die over the circuit structure 90.

The conductive elements 91, 92, and 93 may be disposed between the carrier 11 and the circuit structure 90. Each of the conductive elements 91, 92, and 93 may be disposed on or over the surface 11s2 of the carrier 11. Each of the conductive elements 91, 92, and 93 may be configured to transmit a power between the carrier 11 and the circuit structure 90. In some arrangements, each of the conductive elements 91, 92, and 93 may include a pogo pin, conductive pillar, or other suitable conductive elements.

The DC/DC converter 20 may be configured to provide the DC/DC converter 30 of the packages 81 and 82 with a power by different electrical paths. The DC/DC converter 20 may be configured to provide the DC/DC converter 30 of the packages 81 with a power P2a (e.g., 12V). In some arrangements, the carrier 11 of the packages 81 may be configured to transmit the electrical path conducting the power P2a. The DC/DC converter 20 may be configured to provide the DC/DC converter 30 of the packages 82 with a power P2b (e.g., 12V). In some arrangements, the carrier 11, the conductive element 92, the circuit structure 90, and the conductive element 93 may be configured to transmit the electrical path conducting the power P2b.

In this embodiment, one first power conversion stage may be configured to provide two or more second power conversion stages with a power. By this arrangement, the dimension (e.g., surface area extending along the XY plane) of the electronic device 3 may be reduced

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
an operating module;
a first converter abutting the operating module; and
a second converter opposite to the first converter,
wherein the second converter is configured to convert a first voltage from the first converter to a second voltage received by the operating module.

2. The electronic device of claim 1, wherein the first voltage is greater than the second voltage.

3. The electronic device of claim 1, wherein the first converter and the second converter are collectively configured to function as a voltage regulated module.

4. The electronic device of claim 1, wherein the second converter is configured to provide the operating module with a third voltage different from the second voltage.

5. The electronic device of claim 1, wherein the second converter comprises a plurality of voltage regulators.

6. The electronic device of claim 1, further comprising an encapsulant encapsulating the operating module and separating the first converter from the operating module.

7. The electronic device of claim 6, wherein a lower surface of the encapsulant is at an elevation substantially the same as an elevation of a lower surface of the first converter.

8. The electronic device of claim 1, further comprising:
a first carrier supporting the first converter and the second converter, wherein the first carrier separates the second converter from the operating module.

9. The electronic device of claim 8, further comprising:
a passive component separated from the second converter by the first carrier, wherein the passive component is configured to provide a power path between the second converter and the operating module.

10. The electronic device of claim 9, further comprising:
a second carrier supporting the passive component, wherein the second carrier separates the passive component from the operating module.

11. The electronic device of claim 10, further comprising:
a third carrier separating the operating module from the second carrier, wherein a profile of the third carrier is different from a profile of the second carrier.

12. The electronic device of claim 10, wherein the second carrier laterally overlaps the first converter.

13. The electronic device of claim 8, wherein the first carrier is configured to transmit an electrical path conducting the first voltage and the second voltage.

14. An electronic device, comprising:
an operating module;
a first electrical converter laterally overlapping the operating module; and
a second electrical converter vertically overlapping the operating module) and electrically connected to the first electrical converter with the operating module.

15. The electronic device of claim 14, further comprising a carrier supporting the operating module, wherein the electronic device comprises a plurality of first electrical converters at a peripheral region of the carrier, and the operating module is disposed between at least two of the plurality of first electrical converters.

16. The electronic device of claim 15, wherein the electronic device comprises a plurality of second electrical converters supported by the carrier, and at least one of the plurality of first electrical converters is electrically connected to the operating module through the at least one of the plurality of second electrical converters.

17. The electronic device of claim 16, further comprising:
a power delivery board configured to provide the plurality of first electrical converters with a first voltage and configured to provide the plurality of second electrical converters with a second voltage less than the first voltage.

18. An electronic device, comprising:
a first converter;
a second converter configured to receive a first voltage from the first converter transmitted along a first direction; and
an operating module configured to receive a second voltage from the second converter transmitted along a second direction opposite to the first direction.

19. The electronic device of claim 18, wherein the first converter is configured to convert a third voltage to the first voltage, and the third voltage is transmitted along the second direction.

20. The electronic device of claim 18, further comprising:
a first carrier,
wherein the first converter and the operating module are located at a first side of the first carrier, and the second converter is located at a second side of the first carrier.
